(19) United States
(12) Patent Application Publication
(10) Pub. No.: US 2026/0235370 A1
(43) Pub. Date: Aug. 13, 2026

(54) COOLING DEVICE

(71) Applicant: ACCTON TECHNOLOGY CORPORATION, Hsinchu City (TW)

(72) Inventor: Ting Jui CHANG, Hsinchu City (TW)

(21) Appl. No.: 19/246,642

(22) Filed: Jun. 23, 2025

Related U.S. Application Data
(60) Provisional application No. 63/758,298, filed on Feb. 13, 2025.

(51) Int. Cl. F28F 3/10; F28F 3/02; H05K 7/20

(52) U.S. Cl. CPC F28F 3/10; F28F 3/025; F28F 2240/00; H05K 7/20254

(57) ABSTRACT

A cooling plate includes a body, an upper cover, a first gasket, a floating cover plate, an elastic member, and a second gasket. The body includes a surface, an annular rib protruding from the surface, and a slot extending through the body from the surface. The annular rib defines a liquid cooling area on the surface. The slot is located within the liquid cooling area. The upper cover is covered the surface of the body. The first gasket is disposed between the body and the upper cover and is disposed along the annular rib. The floating cover plate disposed between the body and the upper cover and is covered the slot. The elastic member is positioned between the floating cover plate and the upper cover. The second gasket is disposed between the floating cover plate and the body.

### CROSS-REFERENCE TO RELATED APPLICATION

This application claims priority to US Provisional Application Serial Number 63/758,298, filed February 13, 2025, which is herein incorporated by reference in its entirety.

### BACKGROUND

### Field of Invention

The present invention relates to a cooling device. More particularly, the present invention relates to a cooling device for transceivers.

### Description of Related Art

Currently, most cooling technologies applied to transceivers rely on air cooling. However, as the data transmission rate of transceivers continues to increase, their power consumption also rises. For instance, the power consumption of current 800G and 1600G transceivers ranges from 33W to 40W. As transceivers generate more heat, the overall system requires more powerful cooling solutions. Existing air cooling methods are no longer sufficient to meet these thermal demands.

Therefore, a new cooling device is needed to address the aforementioned issues.

### SUMMARY

The present invention provides a cooling device including a cooling plate. The cooling plate includes a body, an upper cover, a first gasket, a floating cover plate, an elastic member, and a second gasket. The body includes a surface, an annular rib protruding from the surface, and a slot extending through the body from the surface. The annular rib defines a liquid cooling area on the surface. The slot is located within the liquid cooling area. The upper cover is covered the surface of the body. The first gasket is disposed between the body and the upper cover and is arranged along the annular rib. The floating cover plate is disposed between the body and the upper cover and is covered the slot. The elastic member is disposed between the floating cover plate and the upper cover. The second gasket is disposed between the floating cover plate and the body.

In some embodiments, the floating cover plate includes a contact surface facing the surface of the body. The second gasket is positioned between the surface of the body and the contact surface of the floating cover plate.

In some embodiments, the surface of the body includes a groove. The second gasket is received in the groove.

In some embodiments, the body includes an inner edge surface within the slot. The floating cover plate includes an outer edge surface facing the inner edge surface of the body. The second gasket is positioned between the inner edge surface of the body and the outer edge surface of the floating cover plate.

In some embodiments, the outer surface of the floating cover plate includes a groove. The second washer is received in the groove.

In some embodiments, the floating cover plate includes a top surface facing the upper cover and a plurality of fins disposed on the top surface.

In some embodiments, the elastic member is positioned between the top surface of the floating cover plate and the upper cover. The surface includes two flow holes respectively disposed on opposite sides of the liquid cooling area. The elastic member is disposed in a direction parallel to the arrangement of the two flow holes.

In some embodiments, the surface includes two flow holes respectively located on opposite sides of the liquid cooling area. The fins are disposed in a direction parallel to the arrangement of the two flow holes.

In some embodiments, the elastic member is disposed in a direction parallel to the arrangement of the fins.

In some embodiments, the floating cover plate has a contact surface for contacting a heat generating element. The contact surface has a first surface and a second surface. The first surface is parallel to the top surface, and the second surface is inclined from a side of the first surface toward the top surface.

In some embodiments, the cooling device further comprises a connecting pipe. The cooling device further comprises at least two cooling plates. At least one side of each of the at least two cooling plates is connected to a connecting component. The connecting components to which the at least two cooling plates connected are connected to each other by a connecting pipe.

The invention also provides a cooling device. The cooling device includes at least two cooling plates and at least one connecting component. Each of the at least two cooling plates includes a body, an upper cover, a first gasket, a floating cover plate, an elastic member, and a second gasket. The body includes a surface, an annular rib protruding from the surface, a slot extending through the body from the surface, and two drain holes respectively on opposite sides of the body. The annular rib defines a liquid cooling area on the surface. The slot is located within the liquid cooling area. The surface includes two flow holes respectively located on opposite sides of the liquid cooling area. The upper cover is covered the surface of the body. The two drain holes, the two flow holes, the liquid cooling area and the upper cover form a flow space. The first gasket is disposed between the body and the upper cover and is disposed along the annular rib. The floating cover plate is disposed between the body and the upper cover and is covered the slot. The elastic member is disposed between the floating cover plate and the upper cover. The second gasket is disposed between the floating cover plate and the body. The at least one connecting component is connected to one of the two drain holes of one of the two cooling plates and one of the two drain holes of another of the two cooling plates.

In summary, the cooling device disclosed in the disclosure adopts liquid cooling technology to enhance heat dissipation performance. In addition, the cooling device features a floating mechanism that allows for slight adjustments during the installation of heat generating components, enabling proper and secure mounting while maintaining leak prevention. Furthermore, the structural design of the cooling device can be adapted to actual usage requirements, allowing the number of installed heat generating components to be increased or decreased as needed.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic view of a cooling device according to one embodiment of the present disclosure;

FIG. 2 is an exploded view of the cooling device according to one embodiment of the present disclosure;

FIG. 3A is a schematic view of a body according to one embodiment of the present disclosure;

FIG. 3B is a partially enlarged view of the body according to one embodiment of the present disclosure;

FIG. 4A is a front schematic view of the floating cover plate according to one embodiment of the present disclosure;

FIG. 4B is a rear schematic view of the floating cover plate according to one embodiment of the present disclosure;

FIG. 4C is a side schematic view of the floating cover plate according to one embodiment of the present disclosure;

FIG. 4D is another side schematic view of the floating cover plate according to one embodiment of the present disclosure;

FIG. 5 is a partial cross-sectional view of the cooling plate according to one embodiment of the present disclosure;

FIG. 6 is a schematic view of a cooling device according to another embodiment of the present disclosure;

FIG. 7 is a schematic view of a network device according to one embodiment of the present disclosure; and

FIG. 8 is a partial cross-sectional view of the network device according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following disclosure provides numerous different embodiments or examples for implementing various features of the provided subject matter. Specific examples of components and arrangements are described below to simplify the present disclosure. These are, of course, merely examples and are not intended to be limiting in any way. Furthermore, component symbols and/or reference letters may be repeated throughout the various examples of the disclosure. Such repetition is for the sake of simplicity and clarity and, by itself, does not denote any relationship between the various embodiments and/or configurations discussed.

To clearly illustrate the spatial relationship and orientation among components, coordinate axes are shown in the figures: a first axis A1, a second axis A2, and a third axis A3.

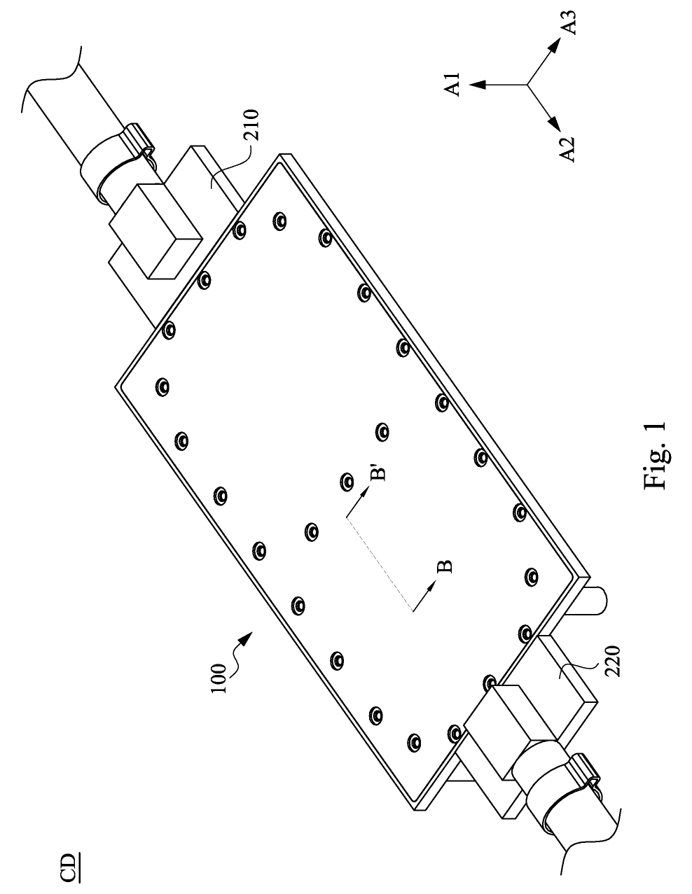

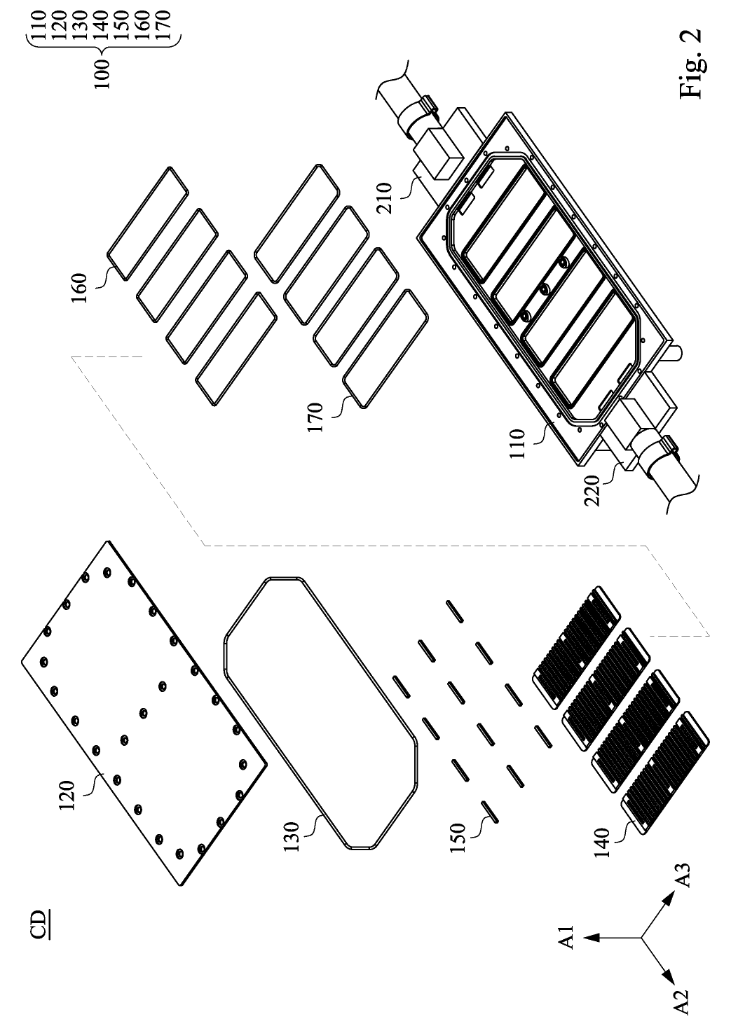

Referring to FIG. 1 and FIG. 2, FIG. 1 illustrates a schematic view, and FIG. 2 illustrates an exploded view of the cooling device CD according to one embodiment of the present disclosure.

In some embodiments, the cooling device CD includes a cooling plate 100 which includes a body 110, an upper cover 120, a first gasket 130, a floating cover plate 140, an elastic member 150, a second gasket 160 and a third gasket 170.

In some embodiments, the body 110, the upper cover 120, and the floating cover plate 140 are made of metal. For water-cooling applications, metal materials with high thermal conductivity and excellent corrosion resistance may be used to ensure efficient heat dissipation and long-term stability. Examples of suitable metals include red copper.

In some embodiments, the material of the first gasket 130, the second gasket 160, and the third gasket 170 includes nitrile rubber (NBR), silicone rubber (SI), fluorine rubber (VITON or FKM), ethylene propylene rubber (EPDM or EPT), polyurethane rubber (PU), or perfluoroelastomer (FFKM).

In some embodiments, the elastic member 150 includes rubber, such as the material of the first gasket 130, the second gasket 160, and the third gasket 170 described above.

In some embodiments, the cooling device CD includes a first connecting component 210 and a second connecting component 220 located on opposite sides of the body 110 of the cooling plate 100. The first connecting component 210 and the second connecting component 220 are configured to be connected to a pipeline supplying cooling fluid into the cooling plate 100, and may be connected to the pipeline in any suitable manner or structure.

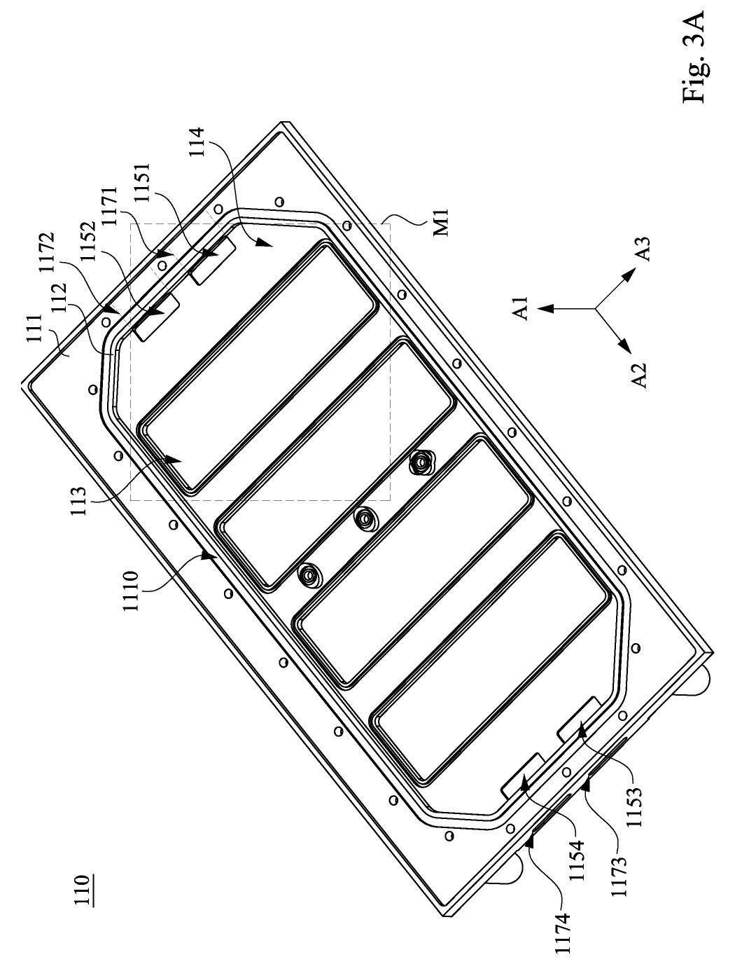

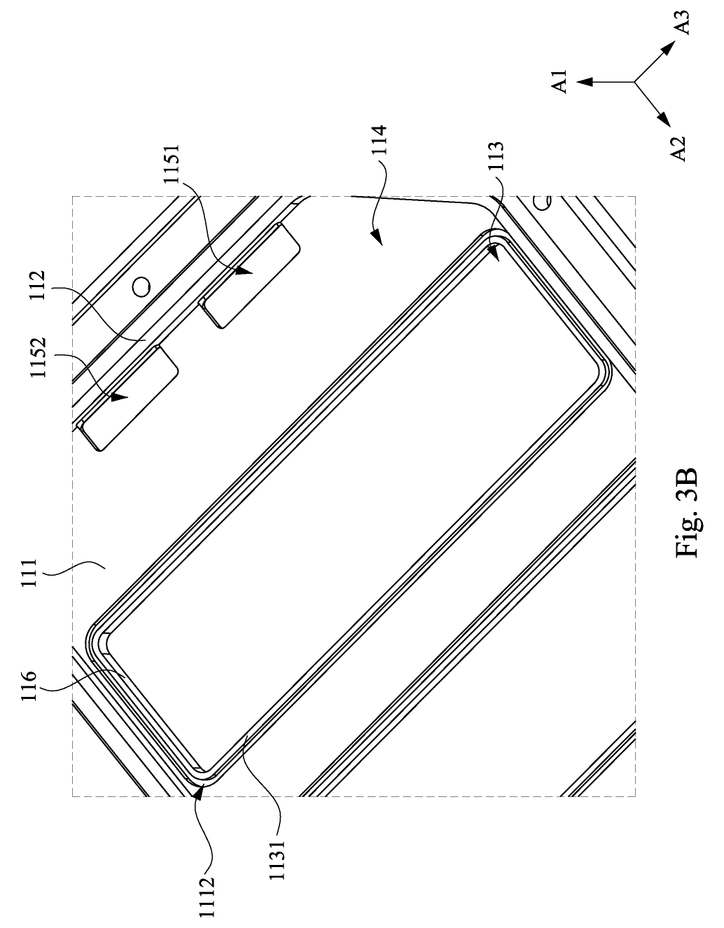

Referring to FIG. 3A which illustrates a schematic view of the body 110. In some embodiments, the body 110 includes a surface 111, an annular rib 112 protruding from the surface 111, and a slot 113 that extend through the body 110 from the surface 111. A liquid cooling area 114 is defined on the surface by the annular rib 112. The slot 113 is located within the liquid cooling area 114. As shown in FIG. 3A, four slots 113 are arranged within the liquid cooling area 114; however, the present disclosure is not limited thereto. In practices, the dimensions of the body 110 and the liquid cooling area 114 may be adjusted as needed to increase or decrease the number of slots 113.

Referring to both FIG. 2 and FIG. 3A. In some embodiments, the upper cover 120 covers the surface 111 of the body 110. The first gasket 130 is positioned between the body 110 and the upper cover 120 and is arranged along the annular rib 112. The elastic member 150 is disposed between the floating cover plate 140 and the upper cover 120. The second gasket 160 and the third gasket 170 are disposed between the floating cover plate 140 and the body 110.

Specifically, a first groove 1110 is formed on the surface 111 of the body 110, surrounding the outer periphery of the annular rib 112, and configured to receive the first gasket 130. When the cooling plate 100 is in the assembled state (as shown in FIG. 1), the upper cover 120 and the liquid cooling area 114 in the body 110 define a liquid-cooling space for containing a cooling liquid. The first gasket 130, disposed around the outer periphery of the annular rib 112, serves to prevent leakage from the liquid-cooling space.

FIG. 3B is a partially enlarged view of the body 110, showing the area enclosed by the dotted line M1 in FIG. 3A. In some embodiments, the body 110 has an inner edge surface 116 within the slot 113. The surface 111 of the body 110 has a second groove 1112 surrounding the slot 113, configured to receive the second gasket 160. In some embodiments, a second surface 1131, which is lower than the surface 111, is formed between the second groove 1112 and the slot 113.

When the cooling plate 100 is in the assembled state (as shown in FIG. 1), the second gasket 160 is disposed in the second groove 1112. The floating cover plate 140 is in contact with the second surface 1131 and covers the second gasket 160. As a result, the second gasket 160 prevents liquid leakage between the floating cover plate 140 and the body 110. The second surface 1131 is positioned lower than the surface 111, thereby forming a space around the slot 113 to accommodate the floating cover plate 140 for quick alignment during assembly.

In some embodiments, the surface 111 of the body 110 has flow holes located on opposite sides within the liquid cooling area 114, the number of which may be adjusted as desired. As illustrated in FIG. 3A, four flow holes-1151, 1152, 1153, and 1154 are formed on opposite sides within the liquid cooling area 114. When the cooling plate 100 is in the assembled state (as shown in FIG. 1), cooling liquid may flow into or out of the liquid-cooling space through the flow holes 1151, 1152, 1153, and 1154, respectively. For example, the liquid may flow into the liquid-cooling space through the flow holes 1151, 1152 and exit through the flow holes 1153, 1154, or vice versa.

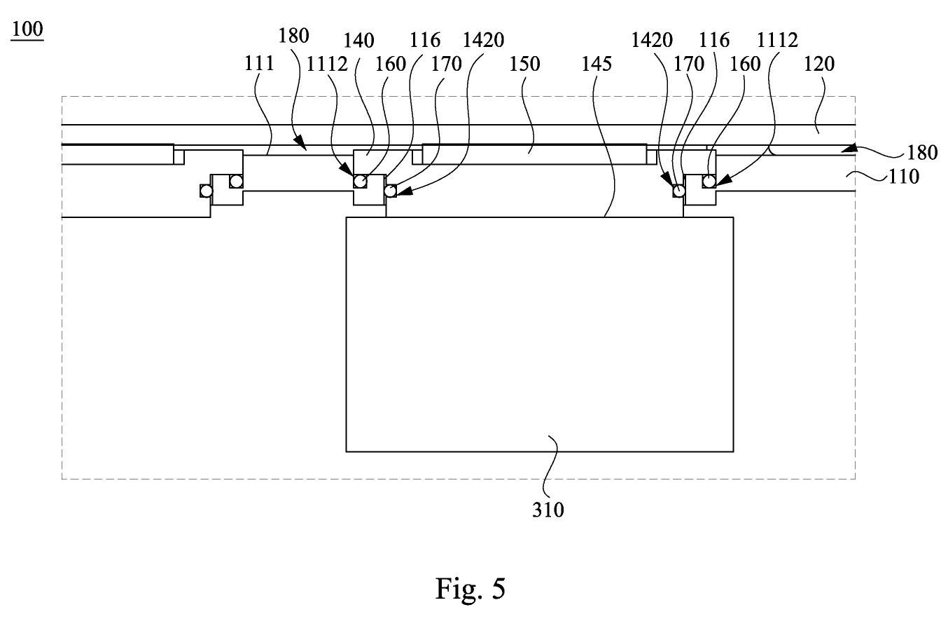

In some embodiments, the body 110 has drain holes on two opposite sides. As illustrated in FIG. 3A, drain holes 1171, 1172, 1173, and 1174 are formed on two opposite sides of the body 110. Each drain holes 1171, 1172, 1173, and 1174 corresponds and is fluidly connected with either the first connecting component 210 or the second connecting component 220. This configuration allows the cooling fluid to flow into or out of the body 110 through the pipelines connected to the first connecting component 210 and the second connecting component 220. The cooling liquid may flow through the communicated drain holes and flow holes, enabling the circulation between exterior of the body 110 and the liquid cooling area 114 through (e.g., the flow holes 1151 are communicating with the drain holes 1171, and so forth). In the assembled state (see FIG. 1), the drain holes 1171 to 1174, the flow holes 1151 to 1154, the liquid cooling area 114, and the upper cover 120 together form a flow space 180 (see FIG. 5).

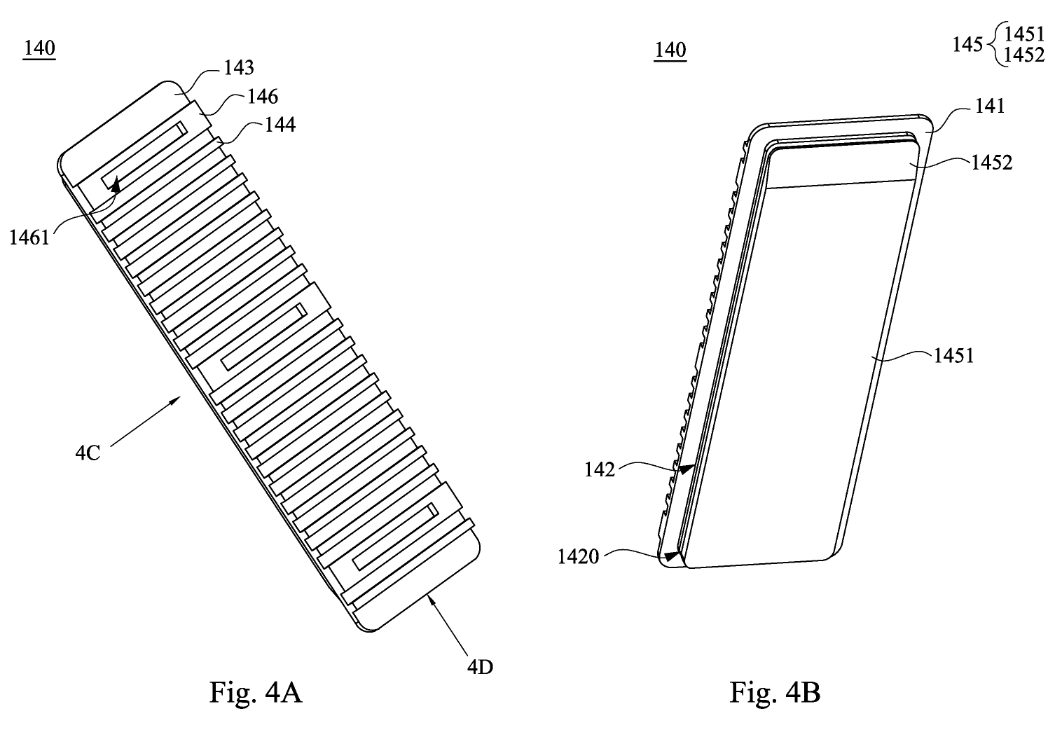

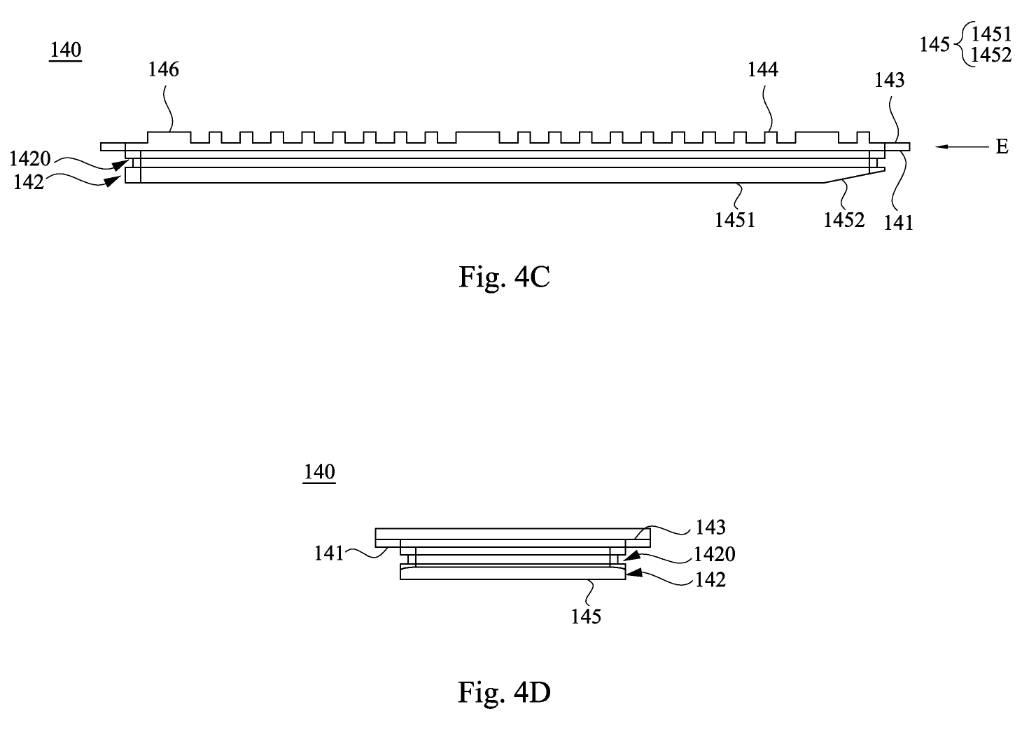

Please refer to FIGS. 4A through 4D, which illustrates a front schematic view, a rear schematic view, a side schematic view, and another side schematic view of the floating cover plate 140, respectively. FIGS. 4C and 4D correspond to side views indicated by arrows 4C and 4D in FIG. 4A, respectively.

Referring to FIG. 4A, in some implementations, the floating cover plate 140 includes a top surface 143 facing the upper cover 120 and a plurality of fins 144 disposed thereon. The fins 144 may be spaced apart from each other. The fins 144 are aligned with the direction of the liquid flow in the liquid cooling area 114 to facilitate smooth liquid flow. For example, the fins 144 may be oriented parallel to the alignment of flow of the flow holes 1151, 1153 or alternatively, to that of flow of the flow holes 1152, 1154 (see FIG. 3A).

In some embodiments, the floating cover plate 140 has a platform 146 disposed on the top surface 143, and a recess 1461 disposed on the platform 146 and configured to hold the elastic member 150. The platform 146 is disposed parallel to the fins 144 so that the recess 1461 is similarly parallel to the fins 144. The top surface 143 may have a plurality of platforms 146 spaced at regular intervals.

Referring to FIG. 4B. In some implementations, the floating cover plate 140 has a body contact surface 141 facing the surface 111 of the body 110. The second gasket 160 is disposed between the surface 111 and the body contact surface 141 of the floating cover plate 140. Specifically, when the cooling plate 100 is in the assembled state (as shown in FIG. 1), the floating cover plate 140 is in contact with the second surface 1131 of the body 110 via the body contact surface 141 and covers the second gasket 160 (see FIGS. 2, 3A, and 3B together).

In some embodiments, the floating cover plate 140 has an outer edge surface 142 facing the inner edge surface 116 of the body 110 (see FIGS. 2 and 3B together). The third gasket 170 is disposed between the inner edge surface 116 of the body 110 and the outer edge surface 142 of the floating cover plate 140. The outer edge surface 142 of the floating cover plate 140 has a third groove 1420 configured to dispose the third gasket 170. When the cooling plate 100 is in the assembled state (as shown in FIG. 1), liquid leakage between the floating cover plate 140 and the body 110 can be prevented by the third gasket 170.

Referring to FIGS. 4B and 4C. In some implementations, the floating cover plate 140 has an element contact surface 145 for contacting a heat generating element. The element contact surface 145 has a first contact surface 1451 and a second contact surface 1452. The first contact surface 1451 is parallel to the top surface 143, while the second contact surface 1452 is inclined, extending from one side of the first contact surface 1451 toward the top surface 143. In some embodiments, the heat generating element may be a fiber optic transceiver, or other element that requires heat dissipation.

Referring to FIG. 4C, during mounting, the heat generating element is inserted from right to left along the element contact surface 145 in the direction of the arrow E. Due to the inclined second contact surface 1452, the heat generating element can be smoothly guided into the mounting position, preventing possible collisions or abrasions caused by sharp edges.

Referring to FIGS. 2, 3A, and 4A. In some embodiments, the elastic member 150 is disposed between the top surface 143 of the floating cover plate 140 and the upper cover 120. The elastic member 150 is disposed in a direction parallel to a direction of arrangement of the two flow holes located on opposite sides of the liquid cooling area 114. For example, the setting direction of the elastic member 150 is parallel to the direction of arrangement of the flow holes 1151, 1153 or parallel to the direction of arrangement of the flow holes 1152, 1154.

In some embodiments, the elastic member 150 is disposed parallel to the fins 144. The elastic member 150 and the fins 144 may be arranged in coordination with each other at set intervals to divide the top surface 143 into a plurality of equally spaced flow paths, allowing the cooling liquid to pass uniformly through the floating cover plate 140.

Referring to FIG. 5, FIG. 5 shows a partial cross-section of the cooling plate 100 where the heat generating element 310 is mounted. The partially cross-section of the cooling plate 100 is sectioned along the cut line B-B' of FIG. 1. In some implementations, the heat generating element 310 is a transceiver.

The cooling plate 100 has a floating function due to the configuration of the floating cover plate 140, the elastic member 150, the second gasket 160, and the third gasket 170. When heat generating element 310 is installed, it can be made to contact the cooling plate 100 appropriately, thereby ensuring optimal thermal performance.

Specifically, during the mounting of the heat generating element 310 to the cooling plate 100, a force resulting from the contact between the heat generating element 310 and the floating cover plate 140 pushes the floating cover plate 140 toward the upper cover 120. During this process, the third gasket 170 slides along the inner edge surface 116, allowing the floating cover plate 140 to move slightly upward, thereby releasing the pressure on the second gasket 160 and compressing the elastic member 150. When the heat generating element 310 is removed from the cooling plate 100, the pressure of the elastic member 150 is released and the restoring force is applied downward by the elastic member 150, thereby repositioning the floating cover plate 140 while simultaneously compressing the second gasket 160.

Thus, the floating cover plate 140, the elastic member 150, the second gasket 160 and the third gasket 170 together form a floating structure. In this floating structure, the elastic member 150 is configured to provide a downward restoring force to return the floating cover plate140 to its original position. The second gasket 160 and the third gasket 170 are configured to achieve dual sealing effect, ensuring waterproof protection and preventing leakage even as the floating cover plate 140 moves up and down. In particular, the third gasket 170 is further configured to slide along the inner edge surface 116, allowing the floating cover plate 140 to float vertically relative to the body 110.

In generally, since the cooling device and the heat generating element are both made of rigid metal, any tolerances or slight errors in installation may make it difficult for the heat generating element to contact the cooling device well and appropriately, resulting in less than expected thermal performance. By means of the floating structure of the cooling plate 100 as described above, the cooling device CD of the present disclosure allows the floating cover plate 140 to cooperate with the floating fine-tuning during the installation of the heat generating element 310, ensuring that the element contact surface 145 of the floating cover plate 140 is fully adhered to the heat generating element 310 for optimal thermal conduction and dissipation performance.

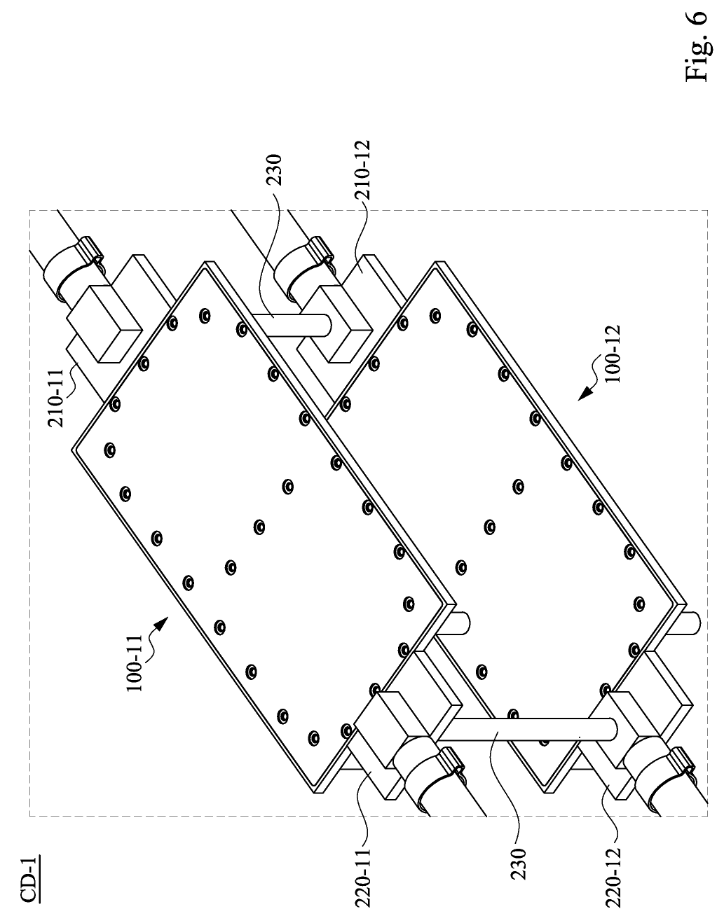

Referring to FIG. 6 which is a schematic view of a cooling device CD-1 according to another embodiment of the present disclosure. In some embodiments, the cooling device CD-1 includes a cooling plate 100-11, a first connecting component 210-11 and a second connecting component 220-11 connecting opposite sides of the cooling plate 100-11, a cooling plate 100-12, a first connecting component 210-12 and a second connecting component 220-12 connecting opposite sides of the cooling plate 100-11, a first connecting pipe 230 connecting the first connecting component 210-11 and the first connecting component 210-12, and a second connecting pipe 240 connecting the second connecting component 220-11 and second connecting component 220-12. The cooling plate 100-11 and the cooling plate 100-12 have the same structure as the cooling plate 100 of the cooling device CD described above. For a detailed description of the structure, please refer to the above description and FIGS. 1 to 5, and will not be repeated herein.

In some embodiments, the first connecting pipe 230 is coupled to the drain holes on the same side of the cooling plates 100-11, 100-12, while the second connecting pipe 240 is coupled to the drain holes on the other side of the cooling plates 100-11, 100-12, so that the cooling liquid can enter both the cooling plates 100-11, 100-12 for heat dissipation.

In some embodiments, the first connecting component 210-11, the first connecting component 210-12, and the first connecting pipe 230 may be integrally formed as one-piece molded structure and regarded as a single connecting component of of the cooling device CD-1. For example, the connecting component may be a manifold connecting both the cooling plate 100-11 and the cooling plate 100-12, or the connection may be made in another form. The same is true for the second connecting component 220-11, the second connecting component 220-12 and the second connecting pipe 240.

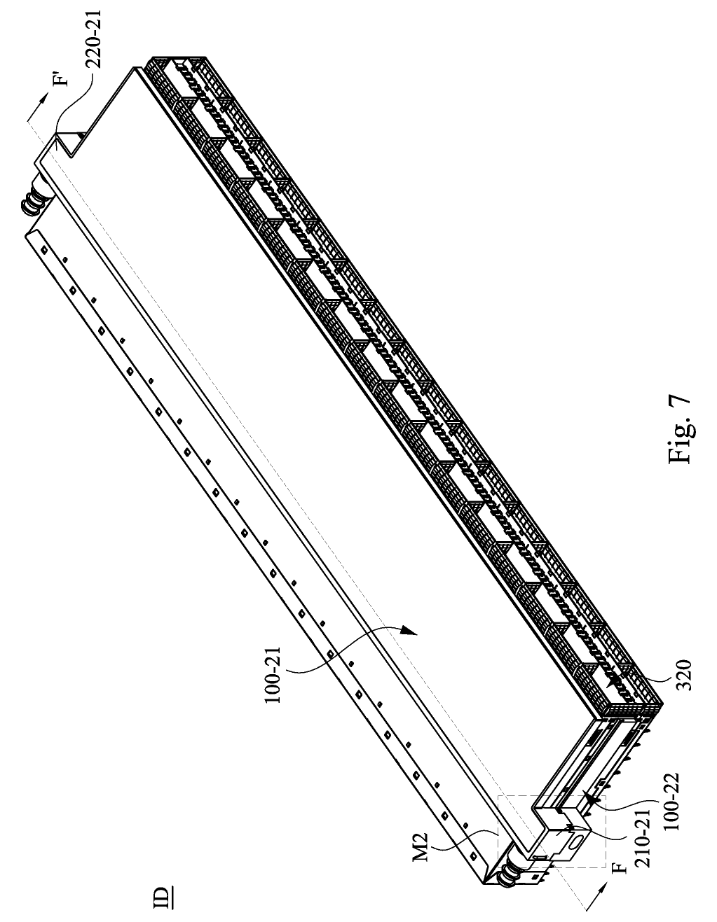

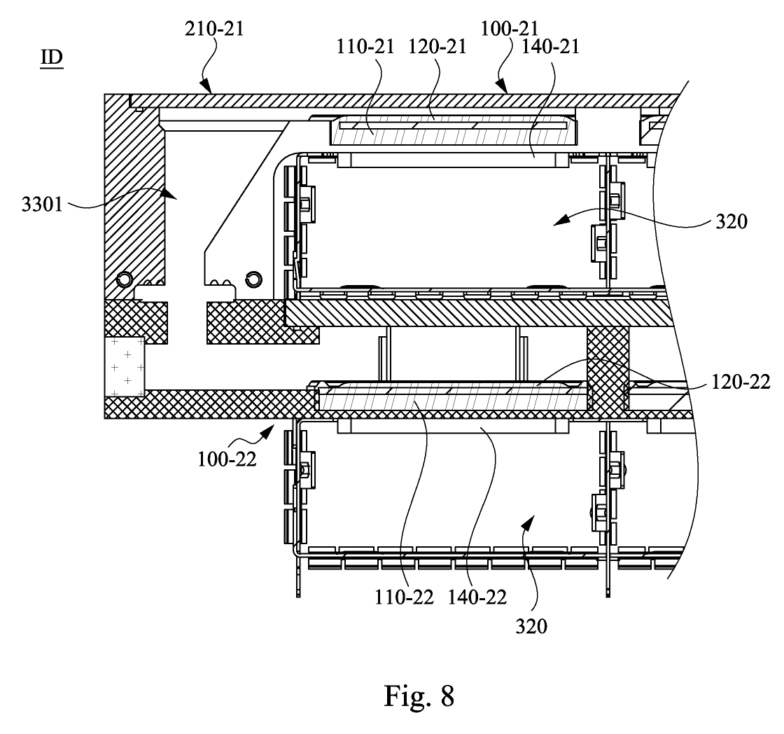

Referring to FIGS. 7 and 8, FIGS. 7 and 8 show an embodiment of the present disclosure’s cooling device applied to a network device, wherein the network device is, for example, a network switch. FIG. 7 is a schematic view of the network device ID. FIG. 8 is a cross-sectional view of the network device ID. FIG. 8 is a section along the cut-line F-F' in FIG. 7 and shows the localized area circled by the dotted line M2.

In FIG. 7, the network device ID includes a cooling plate 100-21, a cooling plate 100-22, a first connecting component 210-21, a second connecting component 220-21, and a communication port 320 for mounting a heat generating element. The first connecting component 210-21 is positioned one side of the cooling plate 100-21,100-22, and connects the cooling plate 100-21, 100-22. The second connecting component 220-21 is positioned another side of the cooling plate 100-21, 100-22, and connects the cooling plate 100-21, 100-22. In one embodiment, the heat generating element is an optical transceiver, and the communication port is used to accommodate the optical transceiver.

In this embodiment, the network device ID has thirty-two communication ports 320 for installing transceivers, but is not limited thereto. Specifically, cooling plate 100-21 is connected to the sixteen communication ports 320 in the upper row of the network device ID, and cooling plate 100-22 is connected to the sixteen communication ports 320 in the lower row of the network device ID. The thirty-two communication ports 320 in the up and down arrangement are cooled by cooling plates 100-21, 100-22, respectively. The communication Port 320 corresponds to the location of one slot and one floating cover plate in the cooling plate. As previously mentioned, the number of slot and floating cover plates may be increased or decreased as appropriate, and thus the number of communication port 320 may be adjusted as needed. In alternative embodiments, the network device ID may have sixty-four communication ports 320 for installing transceivers, but this creation is not limited thereto.

In FIG. 7, the cooling plate 100-21, the cooling plate 100-22, the first connecting component 210-21, and the second connecting component 220-21 are one-piece molded in appearance. The cooling plate 100-21 and the cooling plate 100-22 have the same internal structure as that of the cooling plate 100 described above. For a detailed description of the structure, please refer to the above description and FIGS. 1 to 5, and will not be repeated herein. The first connecting component 210-21 and the second connecting component 220-21 have the same connecting way as that of the cooling device CD-1, and will not be repeated herein.

As shown in the partial cross-sectional view of FIG. 8, in one embodiment, the first connecting component 210-21 includes a fluid flow space 350 that is in communication with both the cooling plate 100-21 and the cooling plate 100-22, allowing cooling liquid to simultaneously flow to both cooling plates 100-21 and 100-22. The upper communication port 320 corresponds to one of the floating cover plate 140-21 of the cooling plate 100-21. The body 110-21, the upper cover 120-21, the floating cover plate 140-21, and the upper communication port 320 together form a structure for mounting a heat generating component, such as a transceiver. The lower communication port 320 corresponds to one of the floating cover plate 140-22 of the cooling plate 100-22. The body 110-22, the upper cover 120-22, the floating cover plate 140-22, and the lower communication port 320 together form another structure for mounting a heat generating component.

In summary, the cooling device of the present disclosure utilizes liquid cooling technology to enhance thermal performance. In addition, the cooling device features a floating structure that allows for fine adjustments during the installation of heat generating elements, thereby enabling secure and proper mounting while maintaining leak prevention. Furthermore, the structural design of the cooling device is adaptable to practical usage requirements, allowing for an increase or decrease in the number of heat generating elements installed.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A cooling device comprising a cooling plate, wherein the cooling plate comprises:
a body including a surface, an annular rib protruding from the surface, and a slot extending through the body from the surface; wherein the annular rib defines a liquid cooling area on the surface, and the slot is located within the liquid cooling area;
an upper cover covering the surface of the body;
a first gasket disposed between the body and the upper cover and arranged along the annular rib;
a floating cover plate disposed between the body and the upper cover and covering the slot;
an elastic member positioned between the floating cover plate and the upper cover; and
a second gasket disposed between the floating cover plate and the body.

2. The cooling device of claim 1, wherein the floating cover plate includes a contact surface facing the surface of the body; and the second gasket is positioned between the surface of the body and the contact surface of the floating cover plate.

3. The cooling device of claim 2, wherein the surface of the body includes a groove; and the second gasket is received in the groove.

4. The cooling device of claim 1, wherein the body includes an inner edge surface within the slot; the floating cover plate includes an outer edge surface facing the inner edge surface of the body; and the second gasket is positioned between the inner edge surface of the body and the outer edge surface of the floating cover plate.

5. The cooling device of claim 4, wherein the outer edge surface of the floating cover plate includes a groove; and the second gasket is received in the groove.

6. The cooling device of claim 1, wherein the floating cover plate includes a top surface facing the upper cover and a plurality of fins disposed on the top surface.

7. The cooling device of claim 6, wherein the elastic member is positioned between the top surface of the floating cover plate and the upper cover; wherein the surface of the body includes two flow holes respectively disposed on opposite sides of the liquid cooling area; and wherein the elastic member is disposed in a direction parallel to the arrangement of the two flow holes.

8. The cooling device of claim 6, wherein the surface of the body includes two flow holes respectively located on opposite sides of the liquid cooling area; and the fins are disposed in a direction parallel to the arrangement of the two flow holes.

9. The cooling device of claim 6, wherein the elastic member is disposed in a direction parallel to the arrangement of the fins.

10. The cooling device of claim 6, wherein the floating cover plate includes a contact surface for contacting a heat generating element; the contact surface includes a first surface and a second surface; the first surface is parallel to the top surface; and the second surface is inclined from a side of the first surface toward the top surface.

11. The cooling device of claim 1, further comprising a connecting pipe; wherein the cooling device further comprises at least two cooling plates; at least one side of each of the at least two cooling plates is connected to a connecting component; and wherein the connecting components to which the at least two cooling plates connected are connected to each other by a connecting pipe.

12. A cooling device, comprising:
at least two cooling plates, wherein each of the at least two cooling plates comprises:
a body including a surface, an annular rib protruding from the surface, a slot extending through the body from the surface, and two drain holes respectively on opposite sides of the body; wherein the annular rib defines a liquid cooling area on the surface; and the slot is located within the liquid cooling area; and wherein the surface includes two flow holes respectively located on opposite sides of the liquid cooling area;
an upper cover covering the surface of the body; wherein the two drain holes, the two flow holes, the liquid cooling area, and the upper cover form a flow space;
a first gasket disposed between the body and the upper cover and arranged along the annular rib;
a floating cover plate disposed between the body and the upper cover and covering the slot;
an elastic member disposed between the floating cover plate and the upper cover; and
a second gasket disposed between the floating cover plate and the body; and
at least one connecting component connecting one of the two drain holes of one of the two cooling plates and one of the two drain holes of another of the two cooling plates.

13. The cooling device of claim 12, wherein the floating cover plate includes a contact surface facing the surface of the body; and the second gasket is positioned between the surface of the body and the contact surface of the floating cover plate.

14. The cooling device of claim 13, wherein the surface of the body includes a groove; and the second gasket is received in the groove.

15. The cooling device of claim 12, wherein the body includes an inner edge surface within the slot; the floating cover plate includes an outer edge surface facing the inner edge surface of the body; and the second gasket is positioned between the inner edge surface of the body and the outer edge surface of the floating cover plate.

16. The cooling device of claim 15, wherein the outer edge surface of the floating cover plate includes a groove; and the second gasket is received in the groove.

17. The cooling device of claim 12, wherein the floating cover plate includes a top surface facing the upper cover and a plurality of fins disposed on the top surface.

18. The cooling device of claim 17, wherein the elastic member is positioned between the top surface of the floating cover plate and the upper cover; wherein the surface of the body includes two flow holes respectively disposed on opposite sides of the liquid cooling area; and wherein the elastic member is disposed in a direction parallel to the arrangement of the two flow holes.

19. The cooling device of claim 17, wherein the surface of the body includes two flow holes respectively located on opposite sides of the liquid cooling area; and the fins are disposed in a direction parallel to the arrangement of the two flow holes.

20. The cooling device of claim 17, wherein the elastic member is disposed in a direction parallel to the arrangement of the fins.
